(19) United States
(12) Patent Application Publication
(10) Pub. No.: US 2023/0175974 A1
(43) Pub. Date: Jun. 8, 2023

(54) INSPECTION SYSTEM INCLUDING SIDE ILLUMINATION UNIT AND INSPECTION METHOD USING THE SAME

(71) Applicant: Samsung Electronics Co., Ltd., Suwon-si (KR)

(72) Inventors: Junghoon CHOI, Seoul (KR); Yunsong JEONG, Yongin-si (KR); Sangyong YU, Hwaseong-si (KR)

(73) Assignee: Samsung Electronics Co., Ltd., Suwon-si (KR)

(21) Appl. No.: 17/940,308

(22) Filed: Sep. 8, 2022

(30) Foreign Application Priority Data
Dec. 8, 2021 (KR) 10-2021-0174618

(51) Int. Cl. G01N 21/88; G01N 21/956

(52) U.S. Cl. CPC G01N 21/8806; G01N 21/956; G01N 2021/95676

(57) ABSTRACT

An inspection system includes a stage unit configured to load a blank mask thereon. A side illumination unit, which is disposed to face a side surface of the blank mask and includes a plurality of LEDs, is provided. A camera disposed adjacent to the blank mask is provided. An inspection light beam irradiated from the side illumination unit toward the side surface of the blank mask is substantially parallel to an upper surface of the blank mask.

### CROSS-REFERENCE TO THE RELATED APPLICATION

This non-provisional patent application claims priority under 35 U.S.C § 119 from Korean Patent Application No. 10-2021-0174618, filed on Dec. 8, 2021, in the Korean Intellectual Property Office, the disclosure of which is incorporated herein by reference in its entirety.

### BACKGROUND

### 1. Field

The example embodiments of the disclosure relate to a blank mask inspection system including a side illumination unit and a blank mask inspection method using the same.

### 2. Description of the Related Art

Various kinds of masks are used in a semiconductor device manufacturing process. The masks are typically formed using a blank mask, therefore a defect of the blank mask may cause various problems in the semiconductor device manufacturing process. Technology for rapidly detecting and accurately inspecting a defect of the blank mask is desired.

### SUMMARY

The example embodiments of the disclosure provide an inspection system and an inspection method which are capable of rapidly and accurately inspecting a defect of a blank mask.

An inspection system according to example embodiments of the disclosure includes a stage unit configured to load a blank mask thereon; a side illumination unit, which is configured to face a side surface of the blank mask and includes a plurality of LEDs; and a camera adjacent to the blank mask is provided.

An inspection method according to example embodiments of the disclosure includes loading a blank mask on a stage unit; irradiating an inspection light beam from a side illumination unit onto the blank mask; And detecting an image of the blank mask using the camera.

An inspection system according to example embodiments of the disclosure includes a stage unit configured to load a blank mask thereon; an illumination unit adjacent to the blank mask and which includes a plurality of LEDs; a camera adjacent to the blank mask; and an image processing unit connected to the camera. The illumination unit includes a side illumination unit configured to irradiate, toward a side surface of the blank mask, an inspection light beam forming an angle between 0 to 10 degrees with respect to an upper surface of the blank mask, an inclined illumination unit configured to irradiate, toward the upper surface of the blank mask, an inspection light beam forming an angle between 15 to 85 degrees with respect to the upper surface of the blank mask, and a vertical illumination unit configured to irradiate, toward the upper surface of the blank mask, an inspection light beam forming an angle between 85 to 90 degrees with respect to the upper surface of the blank mask.

### BRIEF DESCRIPTION OF THE DRAWINGS

FIG. 1 is a schematic view explaining an inspection system according to some example embodiments of the disclosure.

FIG. 2 is a block diagram explaining an inspection system according to some example embodiments of the disclosure.

FIGS. 3 to 8 are layouts explaining a side illumination unit of an inspection system according to some example embodiments of the disclosure.

FIGS. 9 to 11 are sectional views explaining a blank mask according to some example embodiments of the disclosure.

FIGS. 12 to 14 are schematic views explaining an inspection system according to some example embodiments of the disclosure.

FIGS. 15 to 19 are schematic views explaining inspection methods using the inspection system according to some example embodiments of the disclosure.

### DETAILED DESCRIPTION OF EXAMPLE EMBODIMENTS

Various example embodiments will be described more fully hereinafter with reference to the accompanying drawings, in which some example embodiments are shown. In the drawings, like numerals refer to like elements throughout. The repeated descriptions may be omitted.

Elements and/or properties thereof (e.g., structures, surfaces, directions, or the like) that are, e.g., parallel with regard to other elements and/or properties thereof will be understood to be substantially parallel with regard to the other elements and/or properties thereof within manufacturing tolerances and/or material tolerances and/or have a deviation in magnitude and/or angle from “parallel,” or the like with regard to the other elements and/or properties thereof that is equal to or less than 10% (e.g., a. tolerance of ±10%). Similar, elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like and/or may be “substantially perpendicular,” “substantially parallel,” “substantially coplanar,” respectively, with regard to the other elements and/or properties thereof.

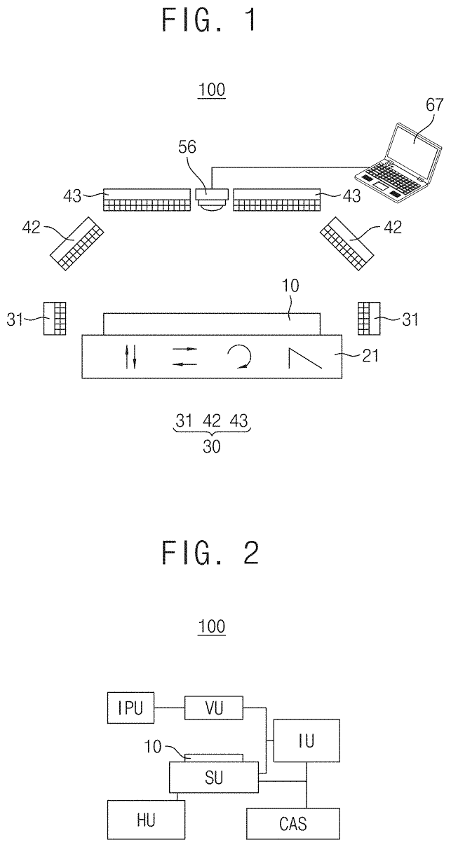

FIG. 1 is a schematic view explaining an inspection system 100 according to some example embodiments of the disclosure.

Referring to FIG. 1, the inspection system 100 according to the example embodiments of the disclosure may include a stage unit 21, an illumination unit 30, a camera 56, and an image processing unit 67. The illumination unit 30 may include a side illumination unit 31, an inclined illumination unit 42, and/or a vertical illumination unit 43.

A blank mask 10 may be loaded on the stage unit 21. The blank mask 10 may have a horizontal width greater than a vertical thickness (e.g., height) thereof. The stage unit 21 may be a unit configured to move the blank mask 10, based on various movement functions. For example, the movement functions may include as horizontal movement, upward or downward movement, rotational movement, inversion movement, inclined movement, and/or a combination thereof.

Each of the illumination units 30 (e.g., side illumination unit 31, the inclined illumination unit 42, and the vertical illumination unit 43) may include a plurality of sources (e.g., light emitting diodes (LEDs)). For example, in some embodiments, each of the side illumination unit 31, the inclined illumination unit 42, and the vertical illumination unit 43 may include at least one of a visible light emitting diode (VLED), an infrared emitting diode (IRED), an ultraviolet light emitting diode (UVLED), a combination thereof, and/or the like. For example, each of the side illumination unit 31, the inclined illumination unit 42, and the vertical illumination unit 43 may include a plurality of visible light emitting diodes (VLEDs). Each of the side illumination unit 31, the inclined illumination unit 42, and the vertical illumination unit 43 may be independently turned on or off. A distance between the blank mask 10 and each of the side illumination unit 31, the inclined illumination unit 42 and the vertical illumination unit 43 may be independently and organically controlled. In some embodiments, at least one of the inclined illumination unit 42 and/or the vertical illumination unit 43 may be omitted.

The side illumination unit 31 may be disposed adjacent to a side surface of the blank mask 10. For example, the side illumination unit 31 may be disposed to face the side surface of the blank mask 10. The side illumination unit 31 may irradiate the inspection light beam toward the side surface of the blank mask 10. In some example embodiments, a center of the side illumination unit 31 may be aligned toward the side surface of the blank mask 10. The side illumination unit 31 may irradiate an inspection light beam toward the side surface of the blank mask 10. In some example embodiments, the side illumination unit 31 may be disposed to irradiate an inspection light beam substantially parallel to an upper and/or lower surface of the blank mask 10.

For example, in some example embodiments, an angle formed by the inspection light beam irradiated from the side illumination unit 31 with respect to the upper surface of the blank mask 10 may be between 0 to 10 degrees. The side illumination unit 31 may be configured to move upwards and downwards, horizontally, and/or to tilt. The distance between the side illumination unit 31 and the blank mask 10 may be controlled. The vertical b of the side illumination unit 31 may be greater than the vertical thickness of the blank mask 10. For example, in some example embodiments, the vertical thickness of the side illumination unit 31 may be 2 or less times the vertical thickness or the blank mask 10.

The inclined illumination unit 42 may be spaced apart from the side illumination unit 31. The inclined illumination unit 42 may be disposed to irradiate an inspection light beam toward the top surface of the blank mask 10 in an inclined direction. In some example embodiments, an angle formed by the inspection light irradiated from the inclined illumination unit 42 (e.g., with respect to the upper surface of the blank mask 10) may be between 15 to 85 degrees.

The vertical illumination unit 43 may be spaced apart from the inclined illumination unit 42 and the side illumination unit 31. The vertical illumination unit 43 may be disposed adjacent to the camera 56. The vertical illumination unit 43 may be disposed to irradiate an inspection light beam to the upper surface of the blank mask 10 in a direction substantially perpendicular. In some example embodiments, an angle formed by the inspection light beam irradiated from the vertical illumination unit 43 with respect to the upper surface of the blank mask 10 may be between 85 to 90 degrees.

The camera 56 may be disposed adjacent to the blank mask 10. The camera 56 may be aligned at various angles with respect to the upper surface of the blank mask 10 through horizontal movement, upward or downward movement, inclined movement, rotational movement, and/or a combination thereof. In some example embodiments, the camera 56 may be aligned with a center of the blank mask 10. The camera 56 may function to detect an image of the blank mask 10.

The camera may include, for example, at least one of a charge coupled device (CCD), a complementary metal oxide semiconductor image sensor (CIS), a combination thereof, and/or the like. In some example embodiments, the camera 56 may include a high-resolution CCD camera. In some example embodiments, the camera 56 may be controlled in linkage with the stage unit 21. In some example embodiments, the camera 56 may be controlled in linkage with the stage unit 21 and the illumination unit 30.

The image processing unit 67 may be connected to the camera 56 in a wired manner, a wireless manner, and/or a combination thereof. The image processing unit 67 may perform functions of receiving, processing, analyzing, and outputting an image of the blank mask 10 detected by the camera 56. The image processing unit 67 may be (and/or be included in) a computer. For example, the image processing unit 67 may be (and/or include) processing circuitry configured to receive, process, analyze, and output the image. The processing circuitry may be, for example, hardware including logic circuits; a hardware/software combination such as a processor executing software; or a combination thereof. In some example embodiments, the processing circuitry more specifically may include, but is not limited to, a central processing unit (CPU), an arithmetic logic unit (ALU), a digital signal processor, a microcomputer, a field programmable gate array (FPGA), and programmable logic unit, a microprocessor, application-specific integrated circuit (ASIC), etc.

FIG. 2 is a block diagram explaining an inspection system 100 according to some example embodiments of the disclosure.

Referring to FIG. 2, the inspection system 100 according to the example embodiments of the disclosure may include a stage unit SU, an illumination unit IU, a camera VU, an image processing unit IPU, a handling unit HU, and a clean air system CAS. The camera VU may be a portion of a high-resolution vision unit.

A blank mask 10 may be loaded on the stage unit SU. In some example embodiments, the stage unit SU may include the stage unit 21 (FIG. 1). The illumination unit IU may be disposed adjacent to the blank mask 10. The illumination unit IU may be movable in linkage with the stage unit SU and the camera VU. In some example embodiments, the illumination unit IU may include the illumination unit 30 (FIG. 1).

The camera VU may be disposed adjacent to the stage unit SU. The camera VU may be aligned toward the blank mask 10. The camera VU may be movable in linkage with the stage unit SU. In some example embodiments, the camera VU may include the camera 56 (FIG. 1). The image processing unit IPU may be connected to the camera VU in a wired manner, a wireless manner, and/or a combination thereof. The image processing unit IPU may perform functions of receiving, processing, analyzing, and outputting an image of the blank mask 10 detected by the camera VU. In some example embodiments, the image processing unit IPU may include the image processing unit 67 (FIG. 1).

The handling unit HU may be disposed adjacent to the stage unit SU. The handling unit HU may perform functions of loading and unloading the blank mask 10 on or from the stage unit SU. The handling unit HU may, for example, include a robotic arm, an actuator, and/or the like. The clean air system CAS may be disposed adjacent to the stage unit SU and the illumination unit IU. The clean air system CAS may function to supply clean air to the stage unit SU, the illumination unit IU, the blank mask 10, the camera VU, and the surroundings thereof. The clean air system CAS may include, for example, a fan, a pressured air source, a filter, a valve, and/or the like. The clean air system CAS may function to prevent pollution of the blank mask 10 and the surroundings thereof. Though not illustrated, the inspection system 100 may be controlled by processing circuitry. For example, the operations of at least one handling unit HU, the clean air system CAS, the illumination unit IU, the camera VU, the stage unit SU, and/or the image processing unit IPU may be controlled based on instructions included in the processing circuitry. In some example embodiments, at least one of the image processing unit IPU and/or the control processing circuitry may identify a defect in the blank mask 10 based on the luminance detected from blank mask 10, as will be described in further detail below. For example, when the camera VU detects a luminance greater than a threshold value, the image processing unit IPU and/or the control processing circuitry may flag the blank mask 10 on the stage unit SU as having a defect, and/or may instruct the handling unit HU to remove the flagged blank mask 10 from production.

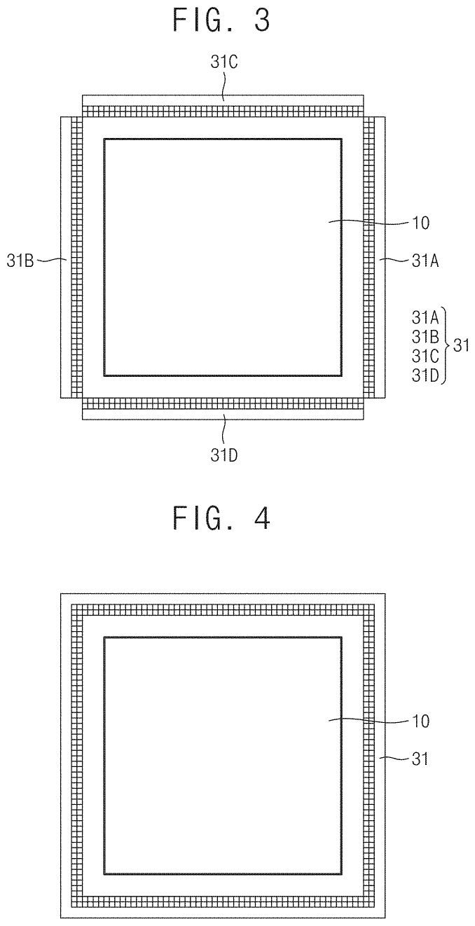

FIGS. 3 to 8 are layouts explaining a side illumination unit 31 of an inspection system according to some example embodiments of the disclosure.

Referring to FIG. 3, the side illumination unit 31 may include a first side illumination unit 31A, a second side illumination unit 31B, a third side illumination unit 31C, and a fourth side illumination unit 31D. The second side illumination unit 31B may be disposed to face the first side illumination unit 31A. A blank mask 10 may be disposed between the first side illumination unit 31A and the second illumination unit 31B. The fourth side illumination unit 31D may be disposed to face the third side illumination unit 31C. The blank mask 10 may be disposed between the third side illumination unit 31C and the fourth side illumination unit 31D. Edges of the first side illumination unit 31A, the second side illumination unit 31B, the third side illumination unit 31C, and the fourth side illumination unit 31D may be adjacent to one another. The first side illumination unit 31A, the second side illumination unit 31B, the third side illumination unit 31C, and the fourth side illumination unit 31D may surround the blank mask 10. Each of the first side illumination unit 31A, the second side illumination unit 31B, the third side illumination unit 31C, and the fourth side illumination unit 31D may be independently turned on or off.

When viewed in a plan view, each of the first side illumination unit 31A, the second side illumination unit 31B, the third side illumination unit 31C, and the fourth side illumination unit 31D may have a width equal to or greater than a width of a corresponding surface of the blank mask 10. For example, the horizontal width of each of the first side illumination unit 31A, the second side illumination unit 31B, the third side illumination unit 31C, and the fourth side illumination unit 31D may be greater than a maximum horizontal width of the blank mask 10. In some example embodiments, the horizontal width of each of the first side illumination unit 31A, the second side illumination unit 31B, the third side illumination unit 31C, and the fourth side illumination unit 31D may be 2 or less times the maximum horizontal width of the blank mask 10. In some example embodiments, the sum of the horizontal widths of the first side illumination unit 31A, the second side illumination unit 31B, the third side illumination unit 31C, and the fourth side illumination unit 31D may be between 1 to 2 times the circumferential length of the blank mask 10.

Referring to FIG. 4, the side illumination unit 31 may surround four sides of a blank mask 10. The side illumination unit 31 may be an integrated type. In some example embodiments, when viewed in a plan view, the side illumination unit 31 may have a quadrangular ring shape. The circumferential length of the side illumination unit 31 may be greater than the circumferential length of the blank mask 10. In some example embodiments, the circumferential length of the side illumination unit 31 may be larger 2 or less times the circumferential length of the blank mask 10. In some example embodiments, the circumferential length of the side illumination unit 31 may be between 1 to 2 times the circumferential length of the blank mask.

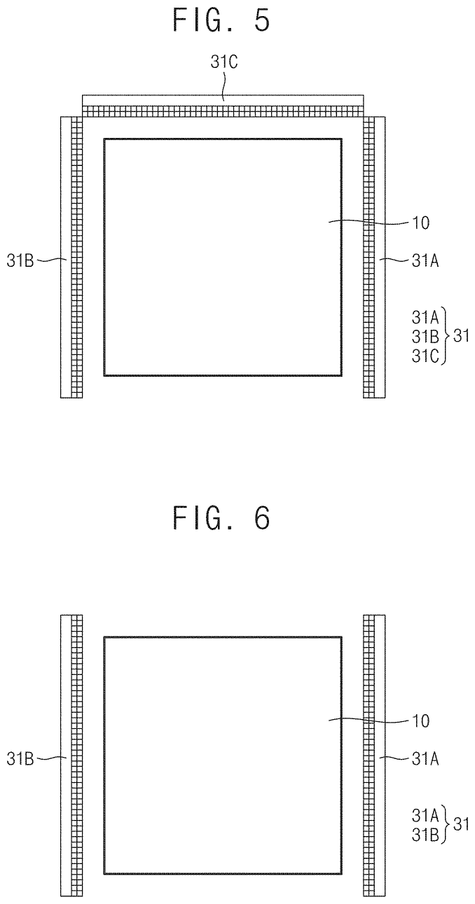

Referring to FIG. 5, the side illumination unit 31 may include a first side illumination unit 31A, a second side illumination unit 31B, and a third side illumination unit 31C. The second side illumination unit 31B may be disposed to face the first side illumination unit 31A. A blank mask 10 may be disposed between the first side illumination unit 31A and the second side illumination unit 31B. The third side illumination unit 31C may be disposed adjacent to the first side illumination unit 31A and the second side illumination unit 31B. The third side illumination unit 31C may be disposed adjacent to a side surface of the blank mask 10. The first side illumination unit 31A, the second side illumination unit 31B, and the third side illumination unit 31C may surround three sides of the blank mask 10.

Referring to FIG. 6, the side illumination unit 31 may include a first side illumination unit 31A and a second side illumination unit 31B. The second side illumination unit 31B may be disposed to face the first side illumination unit 31A. A blank mask 10 may be disposed between the first side illumination unit 31A and the second side illumination unit 31B.

When viewed in a plan view, each of the first side illumination unit 31A and the second side illumination unit 31B may have a greater width than a corresponding surface of the blank mask 10. The horizontal width of each of the first side illumination unit 31A and the second side illumination unit 31B may be greater than a maximum horizontal width of the blank mask 10. The horizontal width of each of the first side illumination unit 31A and the second side illumination unit 31B may be 2 or less times the maximum horizontal width of the blank mask 10.

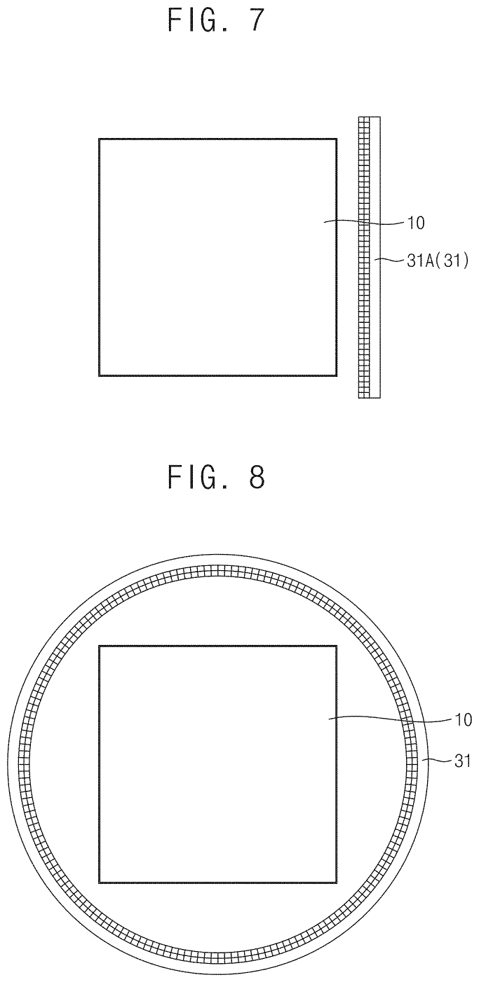

Referring to FIG. 7, the side illumination unit 31 may include a first side illumination unit 31A. The first side illumination unit 31A may be disposed adjacent to a side surface of a blank mask 10. When viewed in a plan view, the first side illumination unit 31A may have a width equal to or greater than that of a corresponding surface of the blank mask 10. The horizontal width of the first side illumination unit 31A may be greater than a maximum horizontal width of the blank mask 10. The horizontal width of the first side illumination unit 31A may be 2 or less times the maximum horizontal width of the blank mask 10.

Referring to FIG. 8, the side illumination unit 31 may surround four sides of a blank mask 10. The side illumination unit 31 may be an integrated type. When viewed in a plan view, the side illumination unit 31 may have a ring shape. A circumferential length (e.g., an internal circumferential length) of the side illumination unit 31 may be greater than the circumferential length of the blank mask 10, and/or the circumferential length of the side illumination unit 31 may be 2 or less times the circumferential length of the blank mask 10.

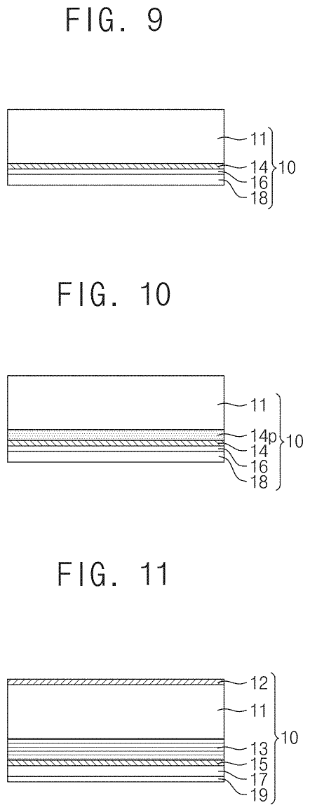

FIGS. 9 to 11 are sectional views explaining a blank mask 10 according to some example embodiments of the disclosure. In some example embodiments, the blank mask 10 may be a blank mask used for manufacture of a semiconductor device. In some example embodiments, the blank mask 10 may have a size of 152 mm×152 mm×6.4 mm. The blank mask 10 may include various kinds of blank masks for, e.g., a binary mask (BIM), for a phase shift mask (PSM), for extreme ultraviolet blank masks, and/or the like.

Referring to FIG. 9, the blank mask 10 may include various kinds of blank masks for a binary mask (BIM). In some example embodiments, the blank mask 10 may include a mask substrate 11, a light shielding layer 14, an anti-reflective coating layer 16, and a resist layer 18.

The mask substrate 11 may include a material having a low impurity content, chemical durability, and a low coefficient of thermal expansion. For example, the mask substrate 11 may include quartz. The light shielding layer 14 may be formed on one surface of the mask substrate 11. In some example embodiments, the light shielding layer 14 may include an optical opaque material for a range of wavelengths of light. For example, the light shielding layer 14 may include a metal layer such as a chromium (Cr) thin film. In some example embodiments, the resist layer 18 may be (and/or include) a photo-set material such that a pattern may be developed onto the resist layer 18. The material of the resist layer 18 may be, for example, selected such that the resist layer 18 may serve as an etch-mask for the light shielding layer 14 in a subsequent process. The anti-reflective coating layer 16 and the resist layer 18 may be sequentially stacked on the light shielding layer 14.

Referring to FIG. 10, a blank mask 10 may include various kinds of blank masks for a phase shift mask (PSM). In some embodiments, the blank mask 10 may include a mask substrate 11, a phase shift layer 14p, a light shielding layer 14, an anti-reflective coating layer 16, and a resist layer 18. The phase shift layer 14p, the light shielding layer 14, the anti-reflective coating layer 16, and the resist layer 18 may be sequentially stacked on one surface of the mask substrate 11. In some example embodiments, the phase shift layer 14p may include, for example, a material with a higher optical density compared to the mask substrate 11, and may be formed to have a thickness such that a phase shift occurs in light transmitted through the phase shift layer 14p. For example, the phase shift layer 14p may include at least one of MoSi, MoSiN, MoSiO, MoSiON, MoSiCN, MoSiCON, a combination thereof, and/or the like. In some example embodiments, the anti-reflective coating layer 16 may be omitted from a blank mask 10 including the phase shift layer 14p.

Referring to FIG. 11, the blank mask 10 may include various kinds of extreme ultraviolet (EUV) blank masks. In some example embodiments, the blank mask 10 may include a mask substrate 11, a backside coating layer 12, a reflective layer 13, a capping layer 15, an absorber layer 17, and an anti-reflective coating layer 19.

The mask substrate 11 may include a low thermal expansion material (LTEM). In some example embodiments, the backside coating layer 12 may be formed on an upper surface of the mask substrate 11. The backside coating layer 12 may include a conductive layer for an electrostatic chuck (ECS chuck). For example, the backside coating layer 12 may include a Cr layer, a CrN layer, a combination thereof, and/or the like. In some example embodiments, the reflective layer 13, the capping layer 15, the absorber layer 17, and the anti-reflective coating layer 19 may be sequentially stacked on a lower surface of the mask substrate 11. The reflective layer 13 may include a UV reflective structure and/or material. For example, the reflective layer 13 may include a structure in which a plurality of Mo layers and a plurality of Si layers are repeatedly alternately stacked. The capping layer 15 may include Ru. The absorber layer 17 may include a structure and/or material which is opaque to UV. For example, the absorber layer 17 may include at least one of TaN, TaBN, a combination thereof, and/or the like.

FIGS. 12 to 14 are schematic views explaining an inspection system 100 according to example embodiments of the disclosure.

Referring to FIG. 12, an inspection system 100 according to some example embodiments of the disclosure may include a stage unit 21, a side illumination unit 31, a camera 56, and an image processing unit 67.

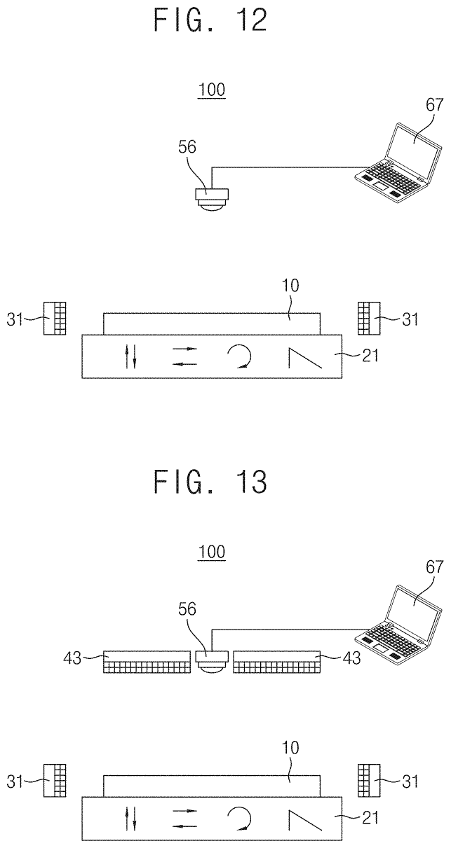

Referring to FIG. 13, an inspection system 100 according to example embodiments of the disclosure may include a stage unit 21, a side illumination unit 31, a vertical illumination unit 43, a camera 56, and an image processing unit 67.

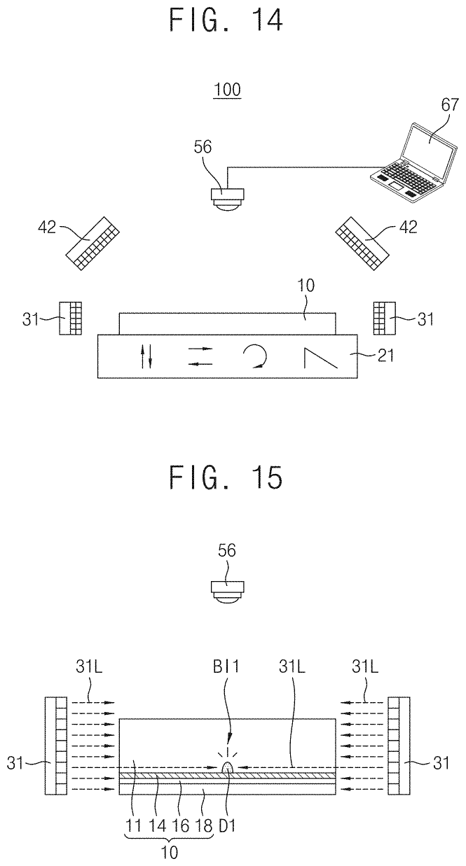

Referring to FIG. 14, an inspection system 100 according to some example embodiments of the disclosure may include a stage unit 21, a side illumination unit 31, an inclined illumination unit 42, a camera 56, and an image processing unit 67.

FIGS. 15 to 19 are schematic views explaining inspection methods using the inspection system according to example embodiments of the disclosure.

Referring to FIG. 15, the side illumination unit 31 may irradiate an inspection light beam 31L toward a side surface of the blank mask 10. The inspection light beam 31L may be substantially parallel to an upper surface of the blank mask 10. In some example embodiments, an angle formed by the inspection light beam 31L irradiated from the side illumination unit 31 with respect to the upper surface of the blank mask 10 may be between 0 to 10 degrees.

The side illumination unit 31 may be disposed to face the side surface of the blank mask 10. The thickness of the side illumination unit 31 may be 1 to 2 times the thickness of the blank mask 10. The thickness of the inspection light beam 31L may be 1 to 2 times the thickness of the blank mask 10. The horizontal width of the side illumination unit 31 may be greater than a maximum horizontal width of the blank mask 10. The horizontal width of the side illumination unit 31 may include configurations similar to those described with reference to FIGS. 3 to 8.

A first defect D1 may be present in the blank mask. For example, the first defect D1 may be present in the mask substrate 11 or between the mask substrate 11 and the light shielding layer 14 adjacent to the light shielding layer 14. For example, the first defect D1 may include a particle, a contamination, a crystal defect, a combination thereof, and/or the like. The mask substrate 11 may function as a light guide for the inspection light beam 31L. The inspection light beam 31L may be irradiated onto the first defect D1 after passing through the mask substrate 11. A first image BI1 may be created from the first defect D1 irradiated with the inspection light beam 31L and the first image BI1 may include a bright image. The first image BI1 may be detected by the camera 56.

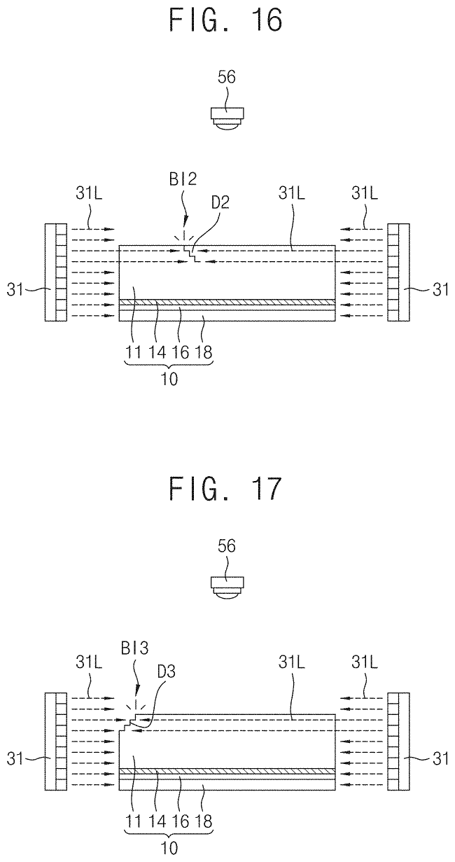

Referring to FIG. 16, a second defect D2 may be present in the mask substrate 11. For example, the second defect D2 may include a crack. The mask substrate 11 may function as a light guide. The inspection light beam 31L may be irradiated onto the second defect D2 after passing through the mask substrate 11. A second image BI2 may be created from the second defect D2 irradiated with the inspection light beam 31L and the second image BI2 may include a bright image. The second image BI2 may be detected by the camera 56.

Referring to FIG. 17, a third defect D3 may be present at a corner or a chamfer of the mask substrate 11. For example, the third defect D3 may include a chip, a crack, a combination thereof, and/or the like. The mask substrate 11 may function as a light guide. The inspection light beam 31L may be irradiated onto the third defect D3 after passing through the mask substrate 11. In addition, the inspection light beam 31L may be directly irradiated onto the third defect D3. A third image BI3 may be created from the third defect D3 irradiated with the inspection light beam 31L and the third image BI3 may include a bright image. The third image BI3 may be detected by the camera 56.

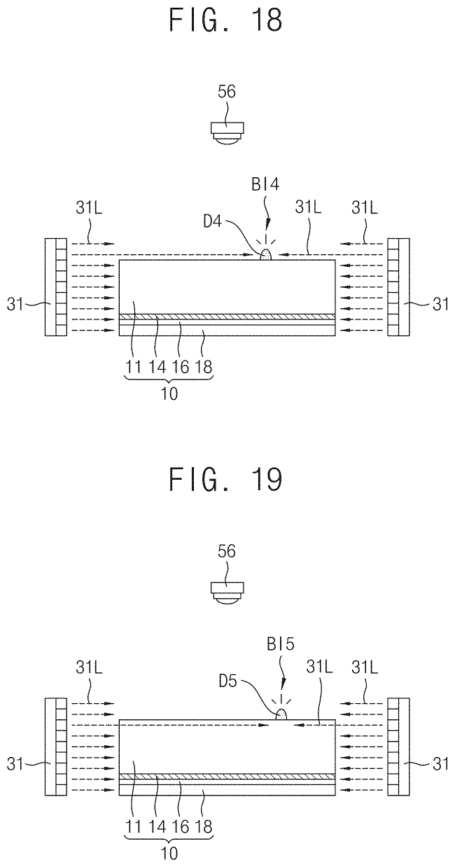

Referring to FIG. 18, a fourth defect D4 may be present on the mask substrate 11. For example, the fourth defect D4 may include a particle, a contamination, a crystal defect, a combination thereof, and/or the like. The inspection light beam 31L may be directly irradiated onto the fourth defect D4. A fourth image BI4 may be created due to irregular surface light reflection of the fourth defect D4 irradiated with the inspection light beam 31L and the fourth image BI4 may include a bright image. The fourth image BI4 may be detected by the camera 56.

Referring to FIG. 19, there may be a fifth defect D5 adjacent to a surface of the mask substrate 11. The fifth defect D5 may have a higher relative index of refraction than the mask substrate 11. For example, the fifth defect D5 may include a particle, a contamination, a crystal defect, a combination thereof, and/or the like. The mask substrate 11 may function as a light guide. The inspection light beam 31L may be irradiated onto the fifth defect D5 after passing through the mask substrate 11. A fifth image BI5 may be created due to refraction from the fifth defect D5 irradiated with the inspection light beam 31L and the fifth image BI5 may include a bright image. The fifth image BI5 may be detected by the camera 56.

Although the inspection methods described with FIGS. 15 to 19 have been illustratively described in conjunction with the case in which the blank mask 10 includes a configuration similar to that of one of various kinds of blank masks for a binary mask, however the example embodiments of the disclosure are not limited thereto, and the inspection methods using the inspection system according to the example embodiments of the disclosure may also be applied to a blank mask including a configuration similar to that of one of various kinds of blank masks such as for a phase shift mask (PSM), various kinds of extreme ultraviolet (EUV) blank masks (e.g., as shown in FIG. 10 and FIG. 11), and/or the like.

Although the inspection methods described with FIGS. 15 to 19 have been illustratively described in conjunction with the case in which the inspection system 100 shown in FIG. 1 includes the side illumination unit 31, the example embodiments of the disclosure are not limited thereto, and the inspection methods according to the example embodiments of the disclosure may also be applied to independent or various combinations of the inspection systems 100 described with reference to FIGS. 1 to 14. For example, the illumination unit 30 may include various combinations of the side illumination unit 31, the inclined illumination unit 42, and the vertical illumination unit 43. Inspection light beams respectively emitted from the side illumination unit 31, the inclined illumination unit 42 and the vertical illumination unit 43 may be irradiated toward the blank mask 10 after being independently, selectively, and/or organically controlled.

In accordance with the inspection methods using the inspection system according to the example embodiments of the disclosure, it may be possible to rapidly detect defects in a wide region of the blank mask 10 (such as a surface, an inside, a corner, a chamfer, and/or the like). For example, the side illumination unit 31 may create both an image through irregular surface light reflection of the blank mask 10 and an image through use of a light guide function of the mask substrate 11.

The side illumination unit 31 may be embodied to have various sizes, shapes, and arrangements, as described with reference to FIGS. 1 to 14. An inspection method capable of rapidly detecting defects in a wide region by various sizes, shapes, and arrangements of the side illumination unit 31 may be provided.

In accordance with the example embodiments of the disclosure, a side illumination unit disposed to face a side surface of a blank mask while including a plurality of LEDs is provided. The side illumination unit may function to irradiate an inspection light beam substantially parallel to an upper surface of the blank mask toward the side surface of the blank mask. It may be possible to effectively detect defects of a surface, an inside, a corner, and a chamfer of the blank mask using the side illumination unit. The horizontal width of the side illumination unit may be greater than a maximum horizontal width of the blank mask. A defect of the blank mask may be rapidly detected. An inspection system and an inspection method, which are capable of rapidly and accurately inspecting a defect of the blank mask, may be provided.

While the example embodiments of the disclosure have been described with reference to the accompanying drawings, it should be understood by those skilled in the art that various modifications may be made without departing from the scope of the disclosure and without changing essential features thereof. Therefore, the above-described embodiments should be considered in a descriptive sense only and not for purposes of limitation.

What is claimed is:

1. An inspection system comprising:
a stage unit configured to load a blank mask thereon;
a side illumination unit configured to face a side surface of the blank mask, the side illumination unit comprising a plurality of LEDs; and
a camera adjacent to the blank mask.

2. The inspection system according to claim 1, wherein the side illumination unit is configured such that an inspection light beam irradiated from the side illumination unit toward the side surface of the blank mask forms an angle between 0 to 10 degrees with respect to an upper surface of the blank mask.

3. The inspection system according to claim 1, wherein the side illumination unit is configured such that an inspection light beam irradiated from the side illumination unit toward the side surface of the blank mask is parallel to an upper surface of the blank mask.

4. The inspection system according to claim 1, wherein the side illumination unit is configured such that a thickness of an inspection light beam irradiated from the side illumination unit toward the side surface of the blank mask is 1 to 2 times a thickness of the blank mask.

5. The inspection system according to claim 1, wherein a horizontal width of the side illumination unit is 1 to 2 times a maximum horizontal width of the blank mask.

6. The inspection system according to claim 1, wherein
the side illumination unit comprises a ring shape; and
an internal circumferential length of the side illumination unit is longer than a circumferential length of the blank mask.

7. The inspection system according to claim 1, further comprising:
a vertical illumination unit adjacent to the camera and spaced apart from the side illumination unit.

8. The inspection system according to claim 7, wherein the vertical illumination unit is configured such that an angle formed by an inspection light beam irradiated from the vertical illumination unit with respect to an upper surface of the blank mask is between 85 to 90 degrees.

9. The inspection system according to claim 7, wherein the vertical illumination unit is configured such that an angle formed by an inspection light beam irradiated from the vertical illumination unit is perpendicular with respect to an upper surface of the blank mask.

10. The inspection system according to claim 1, further comprising:
an inclined illumination unit configured to irradiate an inspection light beam toward an upper surface of the blank mask in an inclined direction.

11. The inspection system according to claim 10, wherein the inclined direction is between 15 to 85 degrees with respect to the upper surface of the blank mask.

12. The inspection system according to claim 1, further comprising:
an image processing unit connected to the camera.

13. An inspection method in the inspection system according to claim 1, comprising:
loading the blank mask on the stage unit;
irradiating an inspection light beam from the side illumination unit onto the blank mask; and
detecting an image of the blank mask using the camera.

14. The inspection method according to claim 13, wherein the inspection light beam irradiated from the side illumination unit toward the side surface of the blank mask forms an angle of between 0 to 10 degrees with respect to an upper surface of the blank mask.

15. The inspection method according to claim 13, wherein the inspection light beam irradiated from the side illumination unit toward the side surface of the blank mask is parallel to an upper surface of the blank mask.

16. The inspection method according to claim 13, wherein the side illumination unit is configured such that a thickness of the inspection light beam irradiated from the side illumination unit toward the side surface of the blank mask is between 1 to 2 times a thickness of the blank mask.

17. The inspection method according to claim 13, wherein a horizontal width of the side illumination unit is 1 to 2 times a maximum horizontal width of the blank mask.

18. The inspection method according to claim 13, wherein:
the side illumination unit comprises a ring shape; and
an internal circumferential length of the side illumination unit is longer than a circumferential length of the blank mask.

19. An inspection system comprising:
a stage unit configured to load a blank mask thereon;
an illumination unit adjacent to the blank mask, the illumination unit comprising a plurality of LEDs;
a camera adjacent to the blank mask; and
an image processing unit connected to the camera,
wherein the illumination unit comprises
a side illumination unit configured to irradiate, toward a side surface of the blank mask, an inspection light beam forming an angle between 0 to 10 degrees with respect to an upper surface of the blank mask,
an inclined illumination unit configured to irradiate, toward the upper surface of the blank mask, an inspection light beam forming an angle between 15 to 85 degrees with respect to the upper surface of the blank mask, and
a vertical illumination unit configured to irradiate, toward the upper surface of the blank mask, an inspection light beam forming an angle between 85 to 90 degrees with respect to the upper surface of the blank mask.

20. The inspection system according to claim 19, wherein the inspection light beam irradiated from the side illumination unit toward the side surface of the blank mask is parallel to the upper surface of the blank mask.
